(19) United States
(12) Patent Application Publication
(10) Pub. No.: US 2022/0270925 A1
(43) Pub. Date: Aug. 25, 2022

(54) FLEXING SEMICONDUCTOR STRUCTURES AND RELATED TECHNIQUES

(71) Applicant: Massachusetts Institute of Technology, Cambridge, MA (US)

(72) Inventors: Vladimir BULOVIC, Lexington, MA (US); Ryan ZIMMERMAN, San Jose, CA (US)

(73) Assignee: Massachusetts Institute of Technology, Cambridge, MA (US)

(21) Appl. No.: 17/628,374

(22) PCT Filed: Jul. 22, 2020
(86) PCT No.: PCT/US20/43124

§ 371 Date: Jan. 19, 2022

Related U.S. Application Data
(60) Provisional application No. 62/876,946, filed on Jul. 22, 2019.

(51) Int. Cl. H01L 21/786; B23K 26/364; H01L 21/56; H01L 21/67; H01L 23/31

(52) U.S. Cl. CPC H01L 21/786; B23K 26/364; H01L 21/568; H01L 21/67092; H01L 23/3114; B23K 2101/40

(57) ABSTRACT

Aspects include a method of fabricating a semiconductor structure including providing a semiconductor layer, scribing the semiconductor layer to provide one or more scribe lines, disposing a flexible support layer on the semiconductor layer, and applying a force to the scribed semiconductor layer so as to induce cracks along the scribe lines.

### CROSS REFERENCE TO RELATED APPLICATIONS

This application claims the benefit of and priority to U.S. Provisional Application No. 62/876,946, filed on Jul. 22, 2019, which is incorporated herein by reference in its entirety.

### STATEMENT REGARDING FEDERALLY SPONSORED RESEARCH

Not Applicable

### FIELD OF THE INVENTION

This disclosure relates generally to semiconductor structures and, more particularly, to flexing semiconductor structures and related fabrication techniques.

### BACKGROUND

Semiconductors are used in a wide range of applications including but not limited to photovoltaics. In recent years, the costs of photovoltaics have decreased resulting in many populations purchasing systems which operate on solar energy. Although overall costs have decreased, a substantial portion of the remaining commercial and residential costs (by some estimates approximately 50%) are related to so-called “soft costs,” which include the distribution, permitting, and installation of solar panels. Much of this cost relates to the weight of the solar panel. Solar panels provided using conventional technology may be approximated as 30 kilograms (kg) per 300 watt panel. Much of this weight results from a glass protective layer and aluminum framing coupled to the semiconductor, which are needed to reduce or prevent bending/flexure, of solar material wafers (typically silicon) in photovoltaic (PV) cells which make up the PV panel and which are relatively thin and fragile.

Reducing or eliminating the amount of glass included in a PV panel would allow the weight of the solar panel to decrease which in turn would reduce soft costs leading to an overall reduction in the cost of a solar panel. One way this has been attempted is through microsystem enabled photovoltaics (MPEV), wherein the micro-scale PV cell is fabricated separately and assembled through a pick-and-place operation. However, MPEV can be costly and requires additional manufacturing steps compared with other approaches.

### SUMMARY

Described are “flexing semiconductors.” As used herein, flexing semiconductors refer to semiconductor structures which are made of inflexible wafers that have been fractured (or fragmented) to make them able to flex (or bend).

In accordance with one aspect of the concepts described herein, a flexing silicon semiconductor is formed or otherwise provided from an inflexible wafer (e.g. an inflexible silicon wafer) that has been fractured (or fragmented) to make them able to flex or bend. With this arrangement a silicon wafer, which is not a flexible semiconductor, can be made into a flexing semiconductor via the fracturing (or fragmenting) process.

With this particular arrangement, a flexing semiconductor is provided. Such a flexing semiconductor finds use in a variety of different applications including photovoltaic cells.

In accordance with a further aspect of the concepts described herein, a method for fabricating a flexing semiconductor structure comprises providing one or more fracture lines in a semiconductor wafer to form a plurality of regions (chiclets) within the semiconductor wafer and inducing fractures (or cracks) along the fracture lines, whereby the fractures allow portions of the semiconductor structure to bend along the facture lines.

With this particular arrangement, a method for forming a flexing semiconductor is provided. By providing fracture lines in a semiconductor, controlled breaks (i.e. breaks or fractures in specific areas of the semiconductor) may be induced formed in the semiconductor by application of force to the semiconductor. The result is designated regions of the semiconductor can bend without forming larger breaks or cracks that may be catastrophic to the operation of the semiconductor circuitry. In an embodiment, the fractures are induced in the semiconductor by stressing the semiconductor.

In accordance with a still further aspect of the concepts described herein, a method for fabricating a flexing semiconductor comprises scribing a semiconductor layer to produce one or more scribe lines, disposing a flexible support layer on the semiconductor layer, and applying a force to the scribed semiconductor layer so as to induce cracks along the scribe lines.

With this particular arrangement, a method for forming a flexing semiconductor is provided. By scribing a semiconductor and then inducing fractures (or cracks or breaks) along the scribe lines, portions of the semiconductor can bend without forming larger cracks that may be catastrophic to the operation of the semiconductor circuitry. In an embodiment, the cracks are induced in the semiconductor by stressing the semiconductor.

In yet another aspect, a singulated semiconductor structure is provided. The singulated semiconductor structure includes a semiconductor wafer scribed along two or more directions so as to provide a plurality of chiclets, a conductor deposited over the plurality of chiclets, and a flexible support layer disposed over at least a portion of the scribed silicon wafer. In embodiments, the semiconductor wafer may be provided as a silicon wafer scribed along two or more directions so as to provide a plurality of chiclets. Such a flexing silicon structure may be used in a photovoltaic (PV) cell where a plurality of such PV cell may make up a PV panel (also sometimes referred to as a “solar” panel).

In a further aspect, a method for fabricating a flexing semiconductor structure is provided. The method includes scribing a semiconductor wafer so as to provide a plurality of scribe lines that form chiclets, forming a grid electrode on the semiconductor wafer, and disposing a flexible support layer over a surface of the semiconductor wafer. The method also includes disposing a conductive layer onto the surface of the flexible support layer and the grid electrode, providing back electrodes to the semiconductor wafer, and stressing the semiconductor wafer to induce cracks along the scribe lines.

### BRIEF DESCRIPTION OF THE DRAWINGS

The concepts, structures, and techniques sought to be protected herein may be more fully understood from the following detailed description of the drawings, in which:

FIG. 1A is an isometric view of a flexing semiconductor structure in accordance with an embodiment;

FIG. 1B is a top view of the flexing semiconductor structure of FIG. 1A in accordance with an embodiment;

FIG. 2 is an isometric view of a flexing semiconductor structure in accordance with another embodiment;

FIG. 3 is a partially exploded, isometric view of a flexing semiconductor structure including encapsulation layers in accordance with a further embodiment;

FIG. 4 is a cross-sectional view of a flexing semiconductor structure in accordance with yet another embodiment;

FIG. 5 is a flow diagram of a process for fabricating a flexing semiconductor structure in accordance with an embodiment; and

FIG. 6 is a flow diagram of a process for fabricating a semiconductor structure in accordance with another embodiment.

It should be noted that the drawings are not necessarily to scale, or inclusive of all elements of a system, emphasis instead generally being placed upon illustrating the concepts, structures, and techniques sought to be protected herein.

### DETAILED DESCRIPTION

In general overview, described are a flexing semiconductor structure and a technique for fabricating a flexing semiconductor structure. Such a flexing semiconductor structure may be formed or otherwise provided by providing fracture lines (also sometimes referred to as break lines, scribe lines or hinge lines) in a semiconductor layer so as to divide the semiconductor layer into multiple sections (or pieces). Upon exertion of a force on the semiconductor layer, the semiconductor layer fractures (or otherwise breaks or cracks) along the predefined fracture lines. The fracture lines are disposed in regions of the semiconductor layer such that when the semiconductor layer fractures in response to a force applied thereto, circuitry on the semiconductor structure remains operational (i.e. the semiconductor circuitry operates in accordance with its normal functions). Thus, the semiconductor structure is able to bend or flex along the fracture lines (i.e. the semiconductor structure is able to flex or bend) and the semiconductor circuitry in the semiconductor structure is still operational (i.e. still operates for its intended purpose).

In one example embodiment, the fracture lines may be formed by scribing (in which case the fracture lines may be referred to as “scribe lines”). In other embodiments, the fracture lines may be provided by cutting or any other technique. Upper and lower layers may then be disposed about the scribed semiconductor layer. Such a process is generally referred to herein as a “singulation process” (or more simply as “singulation”) and results in a semiconductor structure having bendable or hinged regions which impart flexibility to the semiconductor structure. In embodiments, the hinged regions enable portions of the structure to be able to flex while other portions of the structure remain inflexible.

The details of one such illustrative flexing semiconductor structure will be described below in the context of a flexible photovoltaic (PV) cell. However, one of ordinary skill in the art will readily appreciate that a flexing semiconductor structure and the techniques described herein to provide such a structure may find use in a wide variety of different applications (i.e., in application other than PV cells). It should thus be appreciated that although references are sometimes made herein to an illustrative flexible PV cell, such references are made merely to promote clarity in the text and drawings and to promote understanding of the broad concepts described herein.

In an illustrative embodiment, upper and lower encapsulation layers surround the semiconductor structure and may be provided, by way of non-limiting example, as a polymer cover and a backsheet.

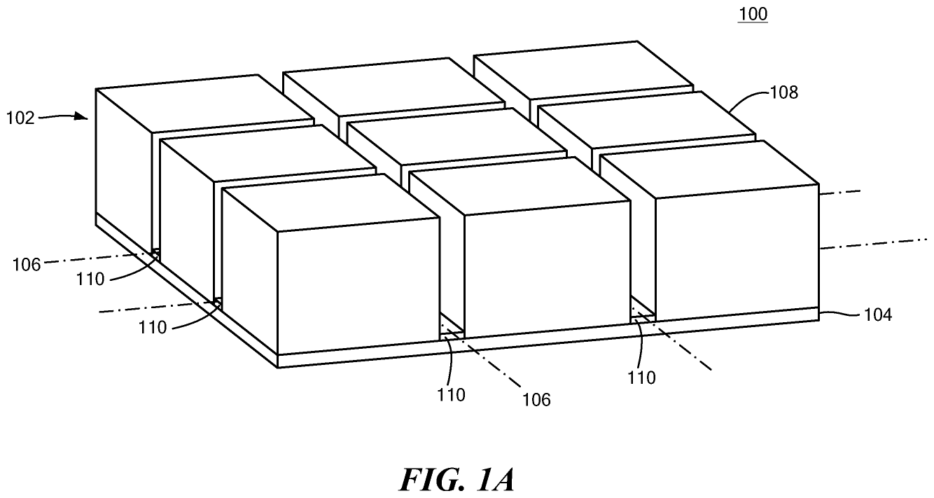

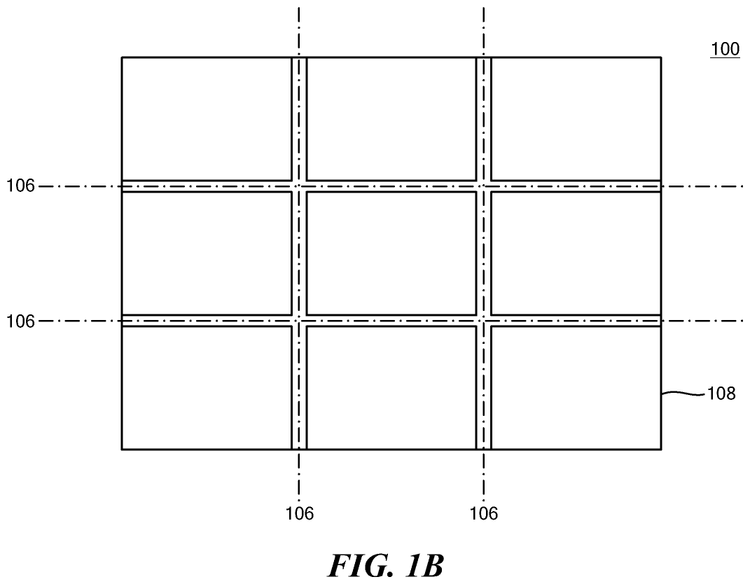

Turning now to FIGS. 1A and 1B, in which like elements are provided having like reference designation, a simplified flexing semiconductor structure 100 includes a semiconductor layer 102 disposed on a support structure 104. As shown in FIGS. 1A-1B, the semiconductor layer 102 is provided having one or more channels (or hinge regions) which impart flexibility to the semiconductor structure 100. In this example embodiment, the hinge regions are arranged in a rectangular grid pattern which thus allows bending of the semiconductor structure in multiple directions (e.g. in two orthogonal directions). In other embodiments, the channels may be provided having other patterns including regular patterns (e.g. triangular, square, oval or circular patterns) or irregular patterns.

In embodiments, the channels may be provided via scribing, direct etching, or any other mechanical, chemical, or substrate forming technique.

In the illustrative embodiment of FIGS. 1A, 1B, as noted above the semiconductor layer 102 is scribed in several locations along two axes to form the grid pattern. The formed channels (e.g. scribed locations 106) result in the formation of chiclets 108. The channels terminate at a hinging layer 110 (also referred to herein as a flexible support layer) that is disposed on the support structure 104 between the chiclets 108. The hinging layer 110 enables flexibility of the structure 100 such that portions of the semiconductor structure 100 may bend while the chiclets 108 themselves remain rigid (i.e. nonflexible).

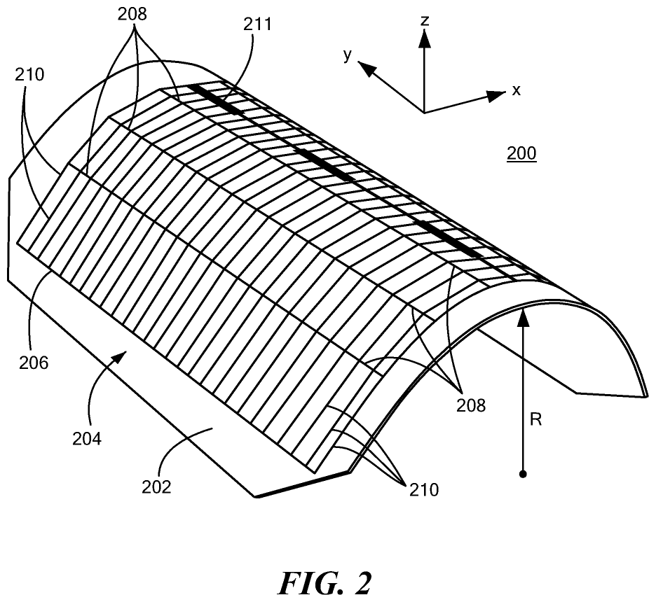

Turning now to FIG. 2, a flexible photovoltaic (PV) or cell 200 comprises a support structure 202 having a flexing semiconductor structure 204 disposed thereover. A PV module (also sometime referred to as a “solar panel” or a “PV panel” or “solar panel”) may be provided from an assembly of such cells 200. In one embodiment, the support structure 202 may be provided as glass, although other materials may also be used.

Since Semiconductor layer 204 is flexing, support structure 202 can be made thin relative to conventional support structures needed for the same size PV cell. For example, support structure 202 may be provided having a thickness in the range of about 0.1 mm to 3 mm. The preferred thickness for a support structure can depend upon the size of the PV chiclets, the size of PV cell, and the size of the PV panel. The support structure should be thick enough so that the PV chiclets do not break under mechanical force (e.g. stress or strain) and that the PV cells are able to hold all of the chicklets together as they are coupled into modules (also referred to as panels) and the modules do not tear apart from the weight of the assembled cells.

A flexing semiconductor layer 204 is disposed over the support structure 202. The manner in which a semiconductor layer 204 may be made flexing will be described in detail herein below and an example of a flexing semiconductor layer 204 will be described in detail hereinbelow. Suffice it here to say that the flexing semiconductor layer 204 is subject to a so-called “singulation” process to form hinges within the structure 200. The support structure 202 acts as a reinforcing layer to stabilize the semiconductor structure 200 in order to reduce (and ideally eliminate) undesirable cracking of the semiconductor layer, which may occur due to excessive or bending (e.g. extreme bending) of the structure 200. Such cracking may occur due to environmental or other causes. Thus, the support structure 202 reduces and ideally eliminates cracking (and particularly eliminates excessive cracking), which could otherwise reduce or prevent the semiconductor structure 200 with its intended purpose (e.g. in the case of PV cell, generating electrical energy).

Semiconductor layer 204 may comprise, e.g., from a silicon wafer. A conductive layer 206 may be disposed or otherwise provided over the semiconductor layer 204.

In embodiments, the semiconductor layer 204 and the conductive layer 206 may then be processed (e.g. scribed or otherwise processes) to create fracture lines 208 (also referred to herein as scribe lines or scribe marks). Any suitable technique may be used to provide the fracture lines. The fracture lines define regions (referred to herein as “chiclets”) in the semiconductor layer 204 and the conductive layer 206. The fracture lines allow controlled fractures (or “breaks” or “cracks”) to form in the semiconductor structure. That is, upon application of a force, the fractures occur along the fracture lines and thus the location of the fractures is controlled to occur in specific regions of the semiconductor structure. These fractures are located to thus make it possible to bend the structure 200. The number and location of the fracture lines 208 may be selected in accordance with a variety of factors including, but not limited to, a desired bending curvature or radius R and the size of the overall structure 200.

It should be noted that in the illustrative embodiment of FIG. 2, the fracture lines are provided in only one direction (i.e. in the y-direction), thus, the structure 200 bends along the x-direction. It should be noted that the structure need not necessarily bend along a radius R as shown in the example of FIG. 2. Rather, the fracture lines may be provided such that bending may occur only in select areas of the semiconductor layer and may occur in any direction enabled by the fracture lines. For example, in some embodiments, it may be desirable that the fracture lines do not extend the entire length of the semiconductor.

When the semiconductor structure 200 is a PV cell, a glass support structure (not shown in FIG. 2) may be disposed over front electrical contacts 210 and terminal contact 211. Since the semiconductor structure can flex, a glass layer which is thinner that glass layers required in prior art approaches may be used in the PV cell. This results in the PV module being lighter than conventional PV module of the same or comparable size.

Furthermore, due to the reduced thickness of the glass layer, the material cost of the PV cell is reduced. Moreover, due to the reduced weight of such a PV cell (i.e. a PV cell having a flexible substrate), the cost of transporting PV panels provided from a plurality of such cells is reduced. For example, the cost of transporting PV panels provided from a plurality of flexible PV cells from a manufacturing facility to a distribution facility may be based, at least in part, upon the weight of the PV panels. Since a substantial portion of PV cell weight is due to the glass layer, reducing the weight of the glass layer, may significantly reduce the weight of the PV cell. Further still, the installation of PV panels may become easier (e.g. less time consuming) and thus less costly when installing a lighter-weight PV panel.

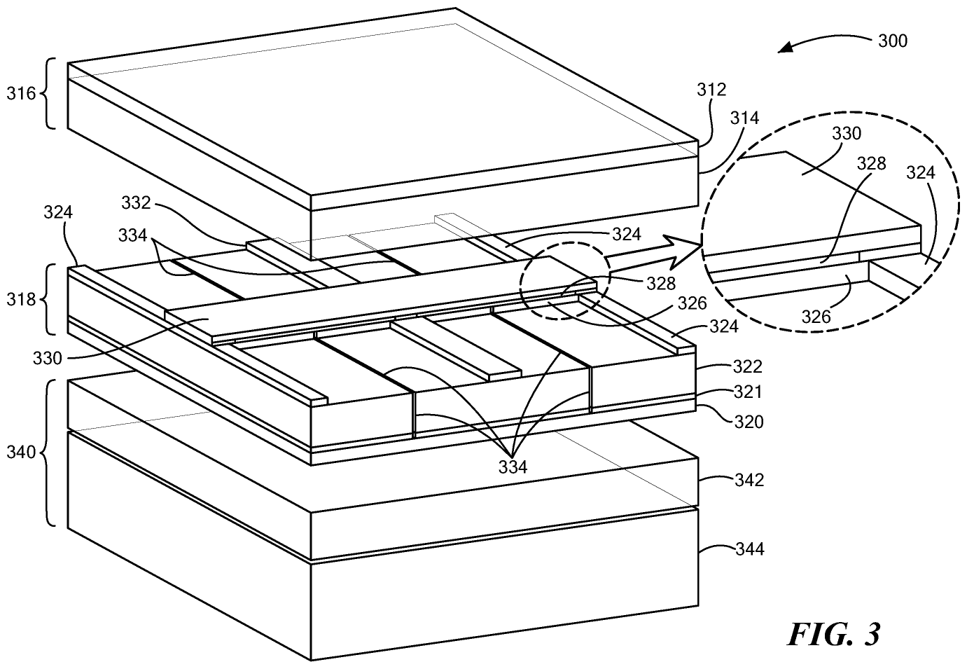

Referring now to FIG. 3, an example flexing semiconductor structure 318 has upper and lower encapsulating layers 316/340 disposed over opposing surfaces thereof.

In this example embodiment, encapsulating layer 340 is comprised of a back sheet 344 and an encapsulant layer 342 that acts as the actual encapsulate. In embodiments, encapsulant layer 342 may comprise a polymer such as a cross linking polymer, for example. In one example embodiment, a commonly used back sheet is a Tedlar back sheet, comprised of Polyvinyl Fluoride (PVF). PVF can be used because it is durable to environmental weathering and staining, as well as because of its resistance to exposure to chemicals resistance. In embodiments, encapsulant layer 342 may comprise Ethylene Vinyl Acetate (EVA) and/or Polydimethylsiloxane (PDMS). EVA is a common cross-linking polymer and may be bonded to or otherwise disposed on backsheet 344 and semiconductor structure 318 to form a seal that prevents moisture ingress. PDMS has a low Young's modulus which results in low (and ideally, minimal) contribution to the bending characteristics of the PV cell while still providing protection from moisture ingress. Materials other than those referenced herein may, of course, also be used to provide the encapsulating layer 340.

Encapsulating layer 340 is disposed over a first surface of the semiconductor structure 318. In the illustrative embodiment is FIG. 3, encapsulating layer 340 is illustrated as being disposed over a lower surface of semiconductor structure 318. However, other arrangements may also be used (e.g. encapsulating layer 340 may be omitted). In FIG. 3, the semiconductor structure 318 includes one or more conductive layers. In this example, the semiconductor structure 318 includes first and second conductive layers 320 and 321, a semiconductor layer 322 and third, fourth, and fifth conductors 324, 326, 332 disposed on a surface of semiconductor layer 322. In one illustrative embodiment, the conductive layers, and conductors may comprise aluminum, copper, and silver among other combinations of any suitable conductive materials including conductive alloys.

Semiconductor layer 322 is disposed over the conductive layer 321. In the embodiment in which the structure of FIG. 3 corresponds to a PV cell, the semiconductor layer 322 may be made from silicon or other Group IV semiconductors.

In some applications (e.g. PV cell or non-PV cell applications), the semiconductor layer may comprise Group III-IV or Group II-VI materials. In some applications, Group III-V semiconductors may be used, including but not limited to gallium arsenide (GaAs) indium gallium arsenide (InGaAs), aluminum gallium arsenide (AlGaAs) and others. It will be understood that other materials may also be used. One of ordinary skill in the art will appreciate how to select one or more particular semiconductor materials for use in a particular application.

To form a flexing semiconductor structure, portions of the semiconductor structure 318 are scribed or otherwise cut or processed to provide fracture lines 344 (also sometimes referred to as scribe lines 334) which allow cracks to propagate in desired locations of the semiconductor upon application of a force. Such resulting fractures or cracks allow the structure 300 to bend without causing catastrophic damage to the semiconductor structure (e.g., where catastrophic damage refers to damage that may cause the structure to malfunction or to stop functioning). Conductive layer 324 is disposed over the semiconductor layer 322. In this example, semiconductor structure 318 includes conductive layers 324, 326, and 332. Silver is a commonly used conductive layer because of its conductive properties and low costs. The conductive layers can be similarly scribed or cut to from fracture lines. When a fracture or break occurs along a fracture line, a so-called chiclet is created. In embodiments, the encapsulating layer 340 may be scribed (or otherwise, cut or scored) similar to semiconductor structure 318.

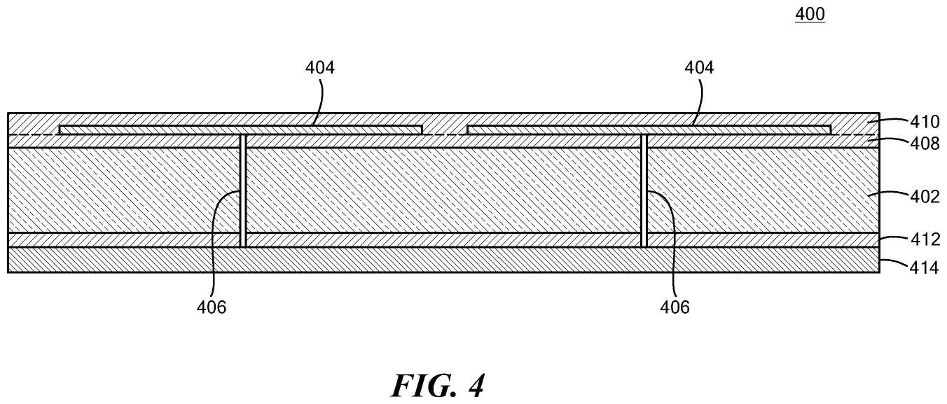

A flexible support material 328 (e.g., polymer layer) is disposed over the conductive layer (e.g., at least layer 326). The flexible material 328 acts as a fracture termination layer (or crack termination layer). In the embodiment of FIG. 3, flexible material 328 is continuously disposed over portions of conductors 324, 326. In other embodiments, (e.g. as will be described below in conjunction with FIG. 4) flexible material 328 may be disposed over selected portions of conductor 326.

As shown in FIG. 3, fracture lines have been provided in the conductive layers 326 and 321 and the semiconductor layer 322. In embodiments, the conductive layers 326 and 321 and the semiconductor layer 322 have been scribed. The regions defined by the fracture lines may be referred to as chiclets. The fracture or scribe lines the cell to fracture (or breaks or crack) in a desirable way, such that the cell can bend while still functioning. This reduces the chances of (and ideally prevents) undesirable breaking or cracking from occurring in the semiconductor layer, which could damage the cell in such a way that the cell does not function for its intended purpose. In embodiments, the flexible support layer 328 may comprise polyimide.

An optional conductive layer 330 may be disposed over flexible support layer 328. The inclusion of the conductive layer 330 depends upon the configuration of the structure 300. The conductive layer 330 may be etched, patterned, or otherwise configured in a pattern to provide electrical contact with the first conductor.

Encapsulating layer 316 is disposed over semiconductor structure 318 of the structure 300. In this illustrative embodiment, encapsulating layer 316 comprises a first (or top) layer or sheet 312 and a second layer 314. The first layer 312 may, for example, be provided from a polymer or from a thermoplastic material. In embodiments, layer 312 may be provided as a PET sheet. Second layer 314 may, for example, be provided from a polymer or from a thermoplastic material. In embodiments, layer 314 may be provided as a polymer layer (for example, layer 314 may be provided as a cross linking polymer). PET sheets may be used as a cross linking polymer to because of its optical clarity, good chemical resistance, and low cost. Other materials may, of course, also be used.

In an embodiment, the encapsulating layer 316 and/or encapsulating layer 340 may be scribed similar to semiconductor portion 318 to create regions defined by the scribe lines (with such regions referred to as “chiclets”). The scribing process may result in scribe lines along which cracks (or breaks) may be formed in the different layers. The resultant cracks impart a flexibility characteristic to the structure (i.e., the breaks function as hinge regions thereby making the cell flexible and allowing the cell to bend as illustrated in FIG. 2). Materials other than those listed may, of course, be used to provide the encapsulating layers 316, 340.

Referring now to FIG. 4, a cross-sectional view of a flexing semiconductor structure 400 will now be described in accordance with an embodiment. As shown in FIG. 4, a semiconductor layer 402 forms the base of the semiconductor structure 400. A flexible support layer 404, which may comprise a polyimide material, is disposed on top of the semiconductor layer 402. In this example embodiment, flexible support later 404 is disposed over selected portions of layer 408. Fracture lines (which may act as fracture termination points or regions) have been formed or otherwise provided in semiconductor layer 402. In embodiments, the semiconductor layer 402 has been scribed to provide a plurality of chiclets having edges defined by scribe lines 406, which in turn act as crack termination points. These scribe lines may be provided in a formulaic way so as to result in a desired scribe pattern. In embodiments, the chiclets are generally square or rectangular shaped, although other shapes are possible. A conductive layer 408 is disposed over the semiconductor layer 402 and may be made out of silver, due to its conductive properties and low cost, although other materials may be used.

As shown in FIG. 4, the semiconductor layer 402 and top conductive layer 408 are also scribed to create chiclets. A flexible support layer (e.g., polymer) may then be deposited over the scribed layers. A second conductive layer 410 may then be deposited over the flexible support layer. Fracture lines have also been formed in conductive layer 408. In embodiments, the semiconductor layer 402 and conductive layer 408 have been scribed to create a plurality of chiclets.

The fracture lines may also be provided in the semiconductor and other layers in a formulaic way. The number and location of the fracture lines may be selected in accordance with a variety of factors including but not limited to the size of the overall structure and a desired bending curvature or radius R of the semiconductor (e.g. as illustrated in the example of FIG. 2). Thus, the extent of flexibility of the structure may be a function of the number and distance between fracture lines.

In addition, the fracture lines should be provided having a size (e.g. width and depth) and cross-sectional shape (e.g., a depth, a width and a shape given the semiconductor material), that is sufficient to concentrate the stress and result in fracturing (or breaking or cracking) along the intended scribe lines.

A base of the semiconductor layer 402 is implemented using one or more conductive layers. In this illustrative embodiment, two conductive layers 412 and 414 are shown in which conductive layer 412 may comprise Aluminum and conductive layer 414 may comprise Copper. Other conductive materials (including other combinations of conductive materials such as conductive alloys or composites) may, of course, also be used.

The semiconductor layer 402 is shown disposed over the conductive layer 412. The semiconductor layer 402 may be made out of Silicon, however, other appropriate materials may include group III-V or II-VI materials. A conductive layer 410 may be made out of silver, although other materials may be used. The flexible support layer 404 is disposed over the conductive layer 408. The conductive layer 408, semiconductor layer 402, and conductive layer 412 are scribed to provide a plurality of chiclets.

The scribing may be implemented using a variety of techniques. In one example, a laser may be used to create scribe lines on specified layers in the structure 400 and at various locations. In an embodiment, each scribe line may be in the range of 20 to 25 μm wide and 80 μm deep, and approximately half-way deep into the structure. The scribe lines may be provided having a size (e.g. width and depth) and cross-sectional shape (e.g., a depth, a width and a shape based on the type of semiconductor material used), which is sufficient to concentrate the stress and result in cracking along the intended scribe lines.

The scribed layers may include the semiconductor layer 402 and one or more of the base conductive layer 412 and the conductive layer 408. In the illustrative example structure of FIG. 4, the base layer 412 is aluminum, the semiconductor layer 402 is silicon, and the conductive layer 408 is silver. The flexible support layer 404 above the conductive layer 408 acts as a crack termination layer, preventing the spread of the cracks. The flexible support layer 404 and the conductive layer 410 act as a backbone to the structure 400, helping to hold the structure together.

The cracking process creates the cracks in the appropriate layers, which are connected through the polymer and electrodes. In an example embodiment in which the conductive layer 412 is aluminum, the semiconductor layer 402 is silicon, and the conductive layer 408 is silver, the cracks would occur in the respective aluminum, silicon, and silver layers. The cracking process may occur at any time after the structure has been scribed. The cracking process may include bending the structure at approximately a 4-inch radius of curvature to initiate the cracks. The cracks may then permeate from the scribe lines 406.

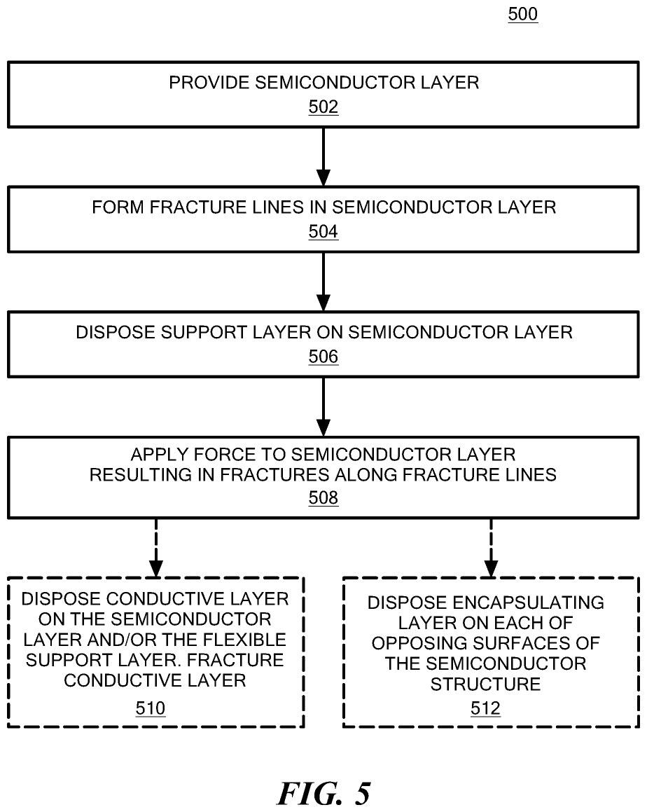

Turning now to FIG. 5, a flow diagram 500 of a process for fabricating a flexible semiconductor structure will now be described in accordance with an embodiment. It will be understood that, unless stated to the contrary, the below-described process steps are unordered (i.e. the steps described below may be performed in any desired or convenient order).

In block 502, a semiconductor layer is provided and, in block 504, fracture lines (e.g. scribe lines) are provided the semiconductor layer. In an embodiment, the fracture lines may be provided using any technique (e.g. any mechanical, optical or electrical techniques) known to those of ordinary skill in the art. For example, the fracture lines may be provided using any mechanical technique or process, chemical technique or process, electrical technique or process, a semiconductor processing technique or a laser technique or process including, but not limited to laser scribing techniques, chemical etching, or pre-forming the substrate with pre-formed fracture indentations. Combinations of the aforementioned techniques may also be used.

In embodiments, the fracture lines may be formed in multiple directions so as to form a pattern. For example, fracture lines may be formed along two directions of the semiconductor layer. For example, fracture lines may be formed along orthogonal axes of the semiconductor layer so as to form a rectangular or square grid pattern. Other fracture patterns, may of course, also be formed including but not limited to triangular, oval or irregular patterns.

In block 506, a flexible support layer is disposed on the semiconductor layer. In an embodiment, the flexible support layer may be comprised of polyimide or a polyimide-grafted polymer.

In block 508, a force is applied to the semiconductor layer resulting in breaks (or cracks) along the fracture lines. The force may be applied using, for example, physical pressure or thermal cycling. As indicated above, the fractures along the fracture lines, in conjunction with the flexible support layer, provide hinged regions such that the semiconductor structure may bend at some sections or regions. Thus, regions or portions of the semiconductor structure are flexible and while other portions are inflexible.

Blocks 510-512 are alternative process steps that may be implemented as shown by the dotted lines in FIG. 5. In block 510, a conductive layer may be disposed on the semiconductor layer and/or the flexible support layer, and the conductive layer may be scribed. In block 512, an encapsulating layer may be disposed on each of the opposing surfaces of the semiconductor structure. The encapsulating layer may be fixed in place to the respective surface of the structure via a bonding technique. The encapsulating layer may be comprised of one of more of Polyvinyl fluoride, Ethylene vinyl acetate, Polydimethylsiloxane, and PET.

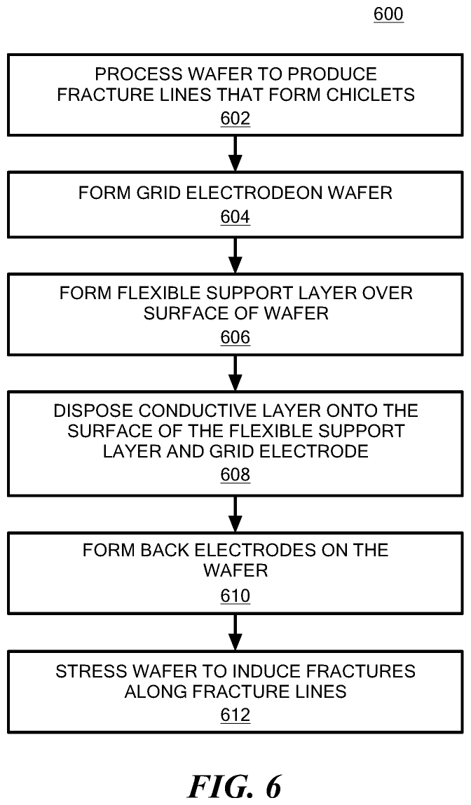

Turning now to FIG. 6, a flow diagram 600 of another process for fabricating a flexing semiconductor structure will now be described in accordance with embodiments. It will be understood that at least one or more portion of the processes described in FIG. 6 may be performed in an order which is different than the order presented in FIG. 6. In block 602, a silicon wafer is processed (e.g. via scribing or any other suitable technique) to produce a plurality of scribe lines that in turn form chiclets. The scribing may include scribing a rear surface of the silicon wafer.

In block 604, a grid electrode is formed on the silicon wafer. In block 606, a flexible support layer (e.g., polyimide) is formed over a surface of the silicon wafer. In block 608, a conductive layer is disposed onto the surface of the flexible support layer and the grid electrode.

In block 610, back electrodes are provided on the silicon wafer. In block 612, the silicon wafer is stressed to induce cracks along the scribe lines. The stressing may be implemented using, e.g., physical pressure applied to the scribe lines or thermal cycling techniques.

As noted above, one application of the singulation technique described herein is in the fabrication of solar cells. In solar cell embodiments, the cell may comprise crystalline Si cells. The Si cells are scribed into smaller pieces (“chiclets”) which are integrated into a polymer cover and a back sheet. The scribing operation also results in pre-determined scribe lines. Applying a force (e.g., stress) to the cells results in cracking of the Si cells along the pre-determined scribe lines. In embodiments, this may be achieved by physically bending the cells. Other techniques to propagate cracks, such as thermal cycling, may also be used.

The integration of the chiclets and with the polymer cover and back sheet essentially form hinges along the scribe lines/cracks within the silicon substrate/wafer. This results in a flexing substrate/wafer. The integration of the chiclets with the polymer cover and back sheet also results in weight reduction. That is, solar cells provided in accordance with the techniques described herein weigh less compared with prior art cells of the same size since the use of the polymer cover and back sheet makes it is possible to avoid using glass as a support structure for the solar cell. The elimination of the glass support structure results in a reduction in the weight of the solar cell. Or, in embodiments in which glass is used, a layer of glass which is thinner than glass layers used in conventional approaches may be used as a support structure.

Flexible solar cells provided in accordance with the techniques described herein are flexible and thus may be disposed on or otherwise applied to uneven surfaces, such as undulating roof surfaces. Also, such flexible solar cells may be suspended (e.g., from a tower or other support structure) and are able to sway in a windy environment (e.g., so as to allow hanging “carpets” of flexible PV cells).

As noted herein above, the “cracking” can be done at any time during the fabrication process. Further, in some embodiments, it may be desirable to use a single cracking process while in other embodiments a plurality of cracking processes may be used. For example, different cracking processes may be used at different points in time during the process of fabrication of a structure (e.g., a flexible solar cell) which comprises a flexing substrate). In embodiments, it may be desirable to pre-crack the semiconductor prior to formation of a final structure. In embodiments, it may be desirable or even necessary to position a scribed semiconductor against either an upper or a lower encapsulating layer and crack the substrate at that point in time. Alternatively still, in some embodiments, it may be desirable or even necessary to form the cracks after forming the entire structure.

Various embodiments which illustrate the concepts sought to be protected are described herein with reference to the related drawings. Alternative embodiments can be devised without departing from the scope of this invention. It is noted that various connections and positional relationships (e.g., over, below, adjacent, etc.) are set forth between elements in the following description and in the drawings. These connections and/or positional relationships, unless specified otherwise, can be direct or indirect, and the present invention is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming or otherwise disposing layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

References in the specification to “one embodiment,” “an embodiment,” “an Example embodiment,” etc., indicate that the embodiment described can include a particular feature, structure, or characteristic, but every embodiment can include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “over,” “overlying,” “atop,” “on top,” “positioned on” or “positioned atop” mean that a first element, such as a first structure, is present on a second element, such as a second structure, where intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements. It should be noted that the term “selective to,” such as, for example, “a first element selective to a second element,” means that the first element can be etched and the second element can act as an etch stop.

It should be appreciated that all of the layers described herein (e.g. dielectric, semiconductor or conductive layers) may be provided using either or both of additive and/or subtractive techniques (e.g. any deposition or etching techniques may be used).

Having described exemplary embodiments, it will now become apparent to one of ordinary skill in the art that other embodiments incorporating their concepts may also be used. The embodiments contained herein should not be limited to disclosed embodiments but rather should be limited only by the spirit and scope of the appended claims. All publications and references cited herein are expressly incorporated herein by reference in their entirety.

Elements of different embodiments described herein may be combined to form other embodiments not specifically set forth above. Various elements, which are described in the context of a single embodiment, may also be provided separately or in any suitable sub combination. Other embodiments not specifically described herein are also within the scope of the following claims.

1. A method for fabricating a semiconductor structure, the method comprising the unordered steps of:
a. providing a semiconductor layer;
b. scribing the semiconductor layer to produce one or more scribe lines;
c. disposing a flexible support layer on the semiconductor layer; and
d. applying a force to the scribed semiconductor layer so as to induce cracks along the scribe lines.

2. The method of claim 1, wherein the cracks along the scribe lines, in conjunction with the flexible support layer, provide hinged regions such that some portions of the semiconductor structure are flexing and other portions of the semiconductor structure are inflexible.

3. The method of claim 1, further comprising disposing a conductive layer onto a surface of the semiconductor layer.

4. The method of claim 3, further comprising scribing the conductive layer.

5. The method of claim 1, wherein scribing the semiconductor layer comprises performing one of: laser scribing, chemical etching, and pre-forming the structure with pre-formed fracture indentations.

6. The method of claim 1, further comprising:
providing a first encapsulating layer and bonding the first encapsulating layer to a first surface of the semiconductor structure; and
providing a second encapsulating layer and bonding the second encapsulating layer to a second surface of the semiconductor structure, the first surface and the second surface comprising opposing surfaces of the semiconductor structure.

7. The method of claim 6, wherein the first encapsulating layer and the second encapsulating layer are comprised of one or more of:
Polyvinyl fluoride;
Ethylene vinyl acetate; and
Polydimethylsiloxane.

8. The method of claim 1, wherein the scribing is performed along two or more directions of the semiconductor layer, and the scribe lines form a grid pattern.

9. The method of claim 1, wherein the flexible support layer comprises polyimide.

10. The method of claim 1, wherein the applying a force to the scribed semiconductor layer is performed by one of:
physical pressure; and
thermal cycling.

11. A singulated semiconductor structure, comprising:
a. a silicon wafer scribed along two or more directions so as to provide a plurality of chiclets;
b. a conductor deposited over the plurality of chiclets; and
c. a flexible support layer disposed over at least a portion the scribed silicon wafer.

12. The semiconductor structure of claim 11, further comprising at least one encapsulating layer disposed over the scribed silicon wafer.

13. The semiconductor structure of claim 12, wherein the at least one encapsulating layer is scribed.

14. The semiconductor structure of claim 12, wherein the at least one encapsulating layer is comprised of one or more of:
Polyvinyl fluoride;
Ethylene vinyl acetate; and
Polydimethylsiloxane.

15. The semiconductor structure of claim 11, wherein the flexible support structure comprises polyimide.

16. A method for fabricating a flexing semiconductor structure comprising the unordered steps of:
a. scribing a semiconductor wafer so as to provide a plurality of scribe lines, the plurality of scribe lines forming chiclets;
b. forming a grid electrode on the semiconductor wafer;
c. disposing a flexible support layer over a surface of the semiconductor wafer;
d. disposing a conductive layer onto the surface of the flexible support layer and the grid electrode;
e. providing back electrodes to the semiconductor wafer; and
f. stressing the semiconductor wafer to induce cracks along the scribe lines.

17. The method of claim 16, wherein scribing the semiconductor wafer comprises scribing a rear surface of the silicon wafer.

18. The method of claim 16, wherein scribing the silicon wafer comprises laser scribing the semiconductor wafer.

19. The method of claim 16, wherein the stressing the semiconductor wafer to induce cracks along the scribe lines is performed by one of: physical pressure; and thermal cycling.

20. The method of claim 16, wherein the flexible support layer comprises polyimide.
